(19) United States
(12) Patent Application Publication
(10) Pub. No.: US 2008/0001628 A1
(43) Pub. Date: Jan. 3, 2008

(54) Level conversion circuit

(75) Inventor: Kyoichi Nagata, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY INC, TOKYO (JP)

(21) Appl. No.: 11/808,045

(22) Filed: Jun. 6, 2007

(30) Foreign Application Priority Data
Jun. 28, 2006 (JP) 2006-177800

(51) Int. Cl. H03K 19/0175

(52) U.S. Cl. 326/63

(57) ABSTRACT

A level conversion circuit includes an input buffer receiving an external signal, cascade-connected inverter circuits arranged in rear of the input buffer, and a switching circuit supplying an internal power supply potential to a power supply terminal of the inverter circuit while an input signal input to the inverter circuit changes from low level to high level, and supplying an external power supply potential to the power supply terminal while the input signal changes from the high level to the low level. The difference between a time necessary for the input signal to exceed a threshold of one of the inverter circuits when the input signal changes from the low level to the high level and time necessary for the input signal to exceed the threshold of the inverter circuit when the input signal changes from the high level to the low level can be thereby reduced.

### TECHNICAL FIELD

The present invention generally relates to a level conversion circuit for converting amplitude of an electric signal, and particularly relates to a level conversion circuit capable of reducing the difference between a rising edge delay of a signal and a falling edge delay thereof due to level conversion.

### BACKGROUND OF THE INVENTION

In recent years, many techniques for reducing an operating voltage of a semiconductor device have been proposed and put to practical use mainly for purposes of reduction of power consumption. There are known some semiconductor devices based on a technique for setting an external voltage to a high voltage similarly to a conventional method and for using a reduced voltage from the high voltage as an internal voltage to ensure compatibility with an existing semiconductor device. In case of a semiconductor device based on such a technique, the amplitude of an external signal or a signal output from an input buffer, to which the external signal is input, is based on the external voltage. It is, therefore, necessary to convert a level of the external signal or the signal output from the input buffer in the semiconductor device.

FIG. 3 is a circuit diagram showing an ordinary level conversion circuit.

The level conversion circuit shown in FIG. 3 includes an input buffer 10 receiving an external signal and inverter circuits 11 and 12 arranged in rear of the input buffer 10 and cascade-connected to each other.

Power supply terminals of the input buffer 10 and the inverter circuit 11 are connected to an external power supply potential VDD. Accordingly, each of a signal A output from the input buffer 10 and a signal B output from the inverter circuit 11 has an amplitude from the external power supply potential VDD to a ground potential VSS. On the other hand, a power supply terminal of the inverter circuit 12 is connected to a dropped internal power supply potential VPERI (<VDD). Accordingly, a signal OUT output from the inverter circuit 12 has an amplitude from the internal power supply potential VPERI to the ground potential VSS. Namely, the signal A at the amplitude of VDD is level-converted into the signal OUT at the amplitude of VPERI by passing through the inverter circuits 11 and 12.

FIG. 4 is a timing chart showing operations performed by the level conversion circuit shown in FIG. 3.

As shown in FIG. 4, the signal B output from the inverter circuit 11 has a predetermined delay from the signal A; however, the difference between a rising edge delay of the signal B and a falling edge delay thereof is substantially zero. This is because the amplitude of an operating voltage of the inverter circuit 11 and that of the signal A are both VDD and the operating voltage and the signal A are not subjected to level conversion during this period.

On the other hand, not only the signal OUT output from the inverter 12 has a predetermined delay from the signal B but also a rising edge delay of the signal OUT is greater than a falling edge delay thereof for the following reason. While the operating voltage of the inverter circuit 12 is VPERI lower than VDD, the signal B input to the inverter 12 has the amplitude of VDD.

In other words, in order to change the level of the signal OUT output from the inverter circuit 12 from low level (VSS) to high level (VPERI), it is necessary to take a period T1 in which the level of the signal B falls from VDD to VPERI/2, where VPERI/2 is a threshold of the inverter 12. The period T1 corresponds to a delay time at a rising edge of the signal OUT. In other words, the period T1 is defined as a period necessary to change the level of the signal B by VDD−(VPER/2).

On the other hand, in order to change the level of the signal OUT from the high level (VPERI) to the low level (VSS), it is necessary to take a period T2 in which the level of the signal B rises from VSS to VPERI/2, where VPERI/2 is the threshold of the inverter circuit 12. The period T2 corresponds to a delay time at a falling edge of the signal OUT. That is, the period T2 is defined as a period necessary to change the level of the signal B by VPERI/2.

In this case, the period T1 corresponding to a change amount of (VDD−(VPER/2)) is longer than the period T2 corresponding to a change amount of VPERI/2 as is obvious from FIG. 4. At VDD=2.5 V and VPERI=1.8, for example, the period T2 corresponds to a change amount of 1.6 V whereas the period T1 corresponds to a change amount of 0.9 V. As a result, the change amount corresponding to the period T2 is nearly twice as large as that corresponding to the period T1.

In this way, if the conventional level conversion circuit is employed, a large imbalance is produced between the rising edge delay of a signal and a falling edge delay thereof due to the level conversion. If such a large imbalance occurs, a setup time or hold time of, for example, an address signal synchronous with a clock is shortened. This disadvantageously hinders operation at high rate.

Japanese Patent Application Laid-open Nos. 2003-332455, 2003-46376, 2002-71760, and 2005-277671 disclose a circuit as a level conversion circuit used for semiconductor devices.

### SUMMARY OF THE INVENTION

The present invention has been achieved to solve the conventional problems, and it is an object of the present invention to provide a level conversion circuit capable of reducing differences between a rising edge delay of a signal and a falling edge delay thereof.

The above and other objects of the present invention can be accomplished by a level conversion circuit comprising:

a first gate circuit receiving an input signal; and

a switching circuit supplying a first power supply voltage to the first gate circuit in a period in which the input signal changes from a first logic level to a second logic level, and supplying a second power supply voltage different from the first power supply voltage to the first gate circuit in a period in which the input signal changes from the second logic level to the first logic level.

According to the present invention, it is possible to reduce the difference between the time necessary for the input signal to exceed a threshold of the first gate circuit when the input signal changes from the first logic level to the second logic level and the time necessary for the input signal to exceed the threshold of the first gate circuit when the input signal changes from the second logic level to the first logic level.

Accordingly, if the first power supply voltage is set lower than the amplitude of the input signal and the second power supply voltage and the first power supply voltage is supplied to a second gate circuit receiving the output from the first gate circuit, then level conversion can be performed between the input signal supplied to the first gate circuit and the output signal output from the second gate circuit, and the difference between the rising edge delay and the falling edge delay can be reduced.

As described above, according to the present invention, the difference between the rising edge delay of the signal and the falling edge delay thereof caused by the level conversion can be reduced. Therefore, it is possible to ensure a sufficient setup time and hold time of, for example, an address signal synchronous with a clock. It is thereby possible to ensure that a semiconductor device using the level conversion circuit according to the aspect of the present invention operates at high rate.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a circuit diagram of a level conversion circuit according to a preferred embodiment of the present invention;

FIG. 2 is a timing chart showing operations performed by the level conversion circuit shown in FIG. 1;

FIG. 3 is a circuit diagram showing an ordinary level conversion circuit; and

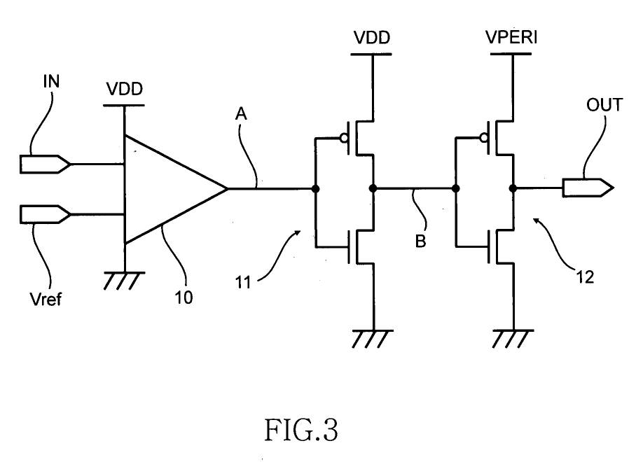

FIG. 4 is a timing chart showing operations performed by the level conversion circuit shown in FIG. 3.

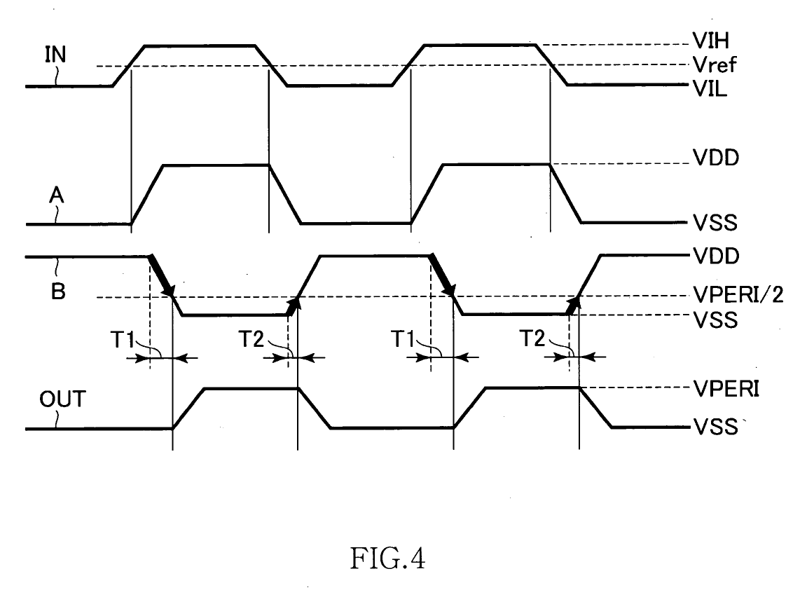

### DETAILED DESCRIPTION OF THE EMBODIMENTS

Preferred embodiment of the present invention will now be explained in detail with reference to the drawings.

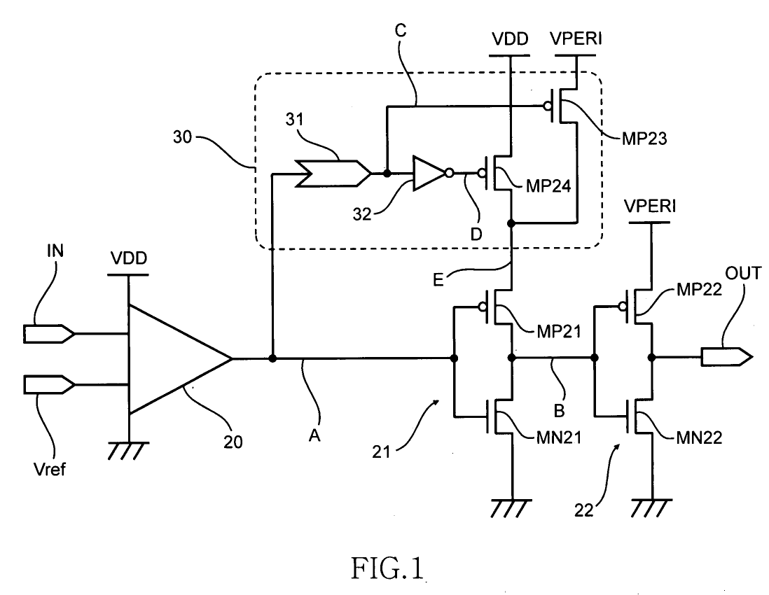

FIG. 1 is a circuit diagram of a level conversion circuit according to a preferred embodiment of the present invention.

As shown in FIG. 1, the level conversion circuit according to the present embodiment includes an input buffer 20 receiving an external signal and inverter circuits 21 and 22 arranged in rear of the input buffer 20 and cascade-connected to each other. The level conversion circuit shown in FIG. 1 is similar in a basic configuration of to ordinary level conversion circuits.

The input buffer 20 is a buffer that receives a signal in the form of, for example, SSTL (Stab Series Terminated Logic). An external signal IN is supplied to one of input terminals of the input buffer 20 whereas a reference voltage Vref is supplied to the other input terminal of the input buffer 20. By so configuring the input buffer 20, a signal A output from the input buffer 20 has an external power supply potential VDD if the external signal IN is higher than the reference voltage Vref, and the signal A has a ground potential VSS if the external signal A is lower than the reference voltage Vref. In other words, the signal A output from the input buffer 20 has an amplitude from the external power supply potential VDD to the ground potential VSS.

The signal A generated as stated above is supplied to the inverter 21 arranged in rear of the input buffer 20 and also supplied to a switching circuit 30.

The inverter circuit 21 includes a P-channel MOS transistor MP21 and an N-channel MOS transistor MN21 connected in series between a power supply terminal E and the ground potential VSS. The signal A output from the input buffer 20 is supplied in common to gate electrodes of the transistors MP21 and MN21.

Meanwhile, the switching circuit 30 includes a delay circuit 31 receiving the signal A, an inverter circuit 32 inverting a signal C output from the delay circuit 31 and generating a signal D, a P-channel MOS transistor MP23 receiving the signal C, and a P-channel MOS transistor MP24 receiving the signal D. The transistors MP23 and MP24 function as a power supply circuit supplying a power supply voltage to the power supply terminal E of the inverter circuit 21. Because the signals C and D are complementary to each other, the transistors MP23 and MP24 exclusively turn ON.

As shown in FIG. 1, a source of the transistor MP23 is connected to an internal power supply potential VPERI and a source of the transistor MP24 is connected to an external power supply potential VDD. Drains of the transistors MP23 and MP24 are connected in common to the power supply terminal E of the inverter circuit 21, that is, connected in common to a source of the transistor MP21. The internal power supply potential VPERI is a potential obtained by reducing the external power supply potential VDD within a semiconductor device.

A delay produced by the delay circuit 31 is set smaller than a signal width. The “signal width” signifies an effective data width of the external signal IN and corresponds to a time from a rising edge of the signal A to a fall edge thereof and to a time from the falling edge to the rising edge thereof. If the signal width is not constant, the delay produced by the delay circuit 31 is set smaller than a minimum signal width. By so setting, the signal C output from the delay circuit 31 rises before a level of the signal A changes from high level (VDD) to low level (VSS), and falls before the level of the signal A changes from the low level (VSS) to the high level (VDD).

Furthermore, the delay produced by the delay circuit 31 is set larger than a rising time of the signal A and a falling time of the signal A. Namely, while it takes a certain time for the signal A to change from the high level (VDD) to the low level (VSS) or change in an opposite direction, the delay produced by the delay circuit 31 is set larger than the certain time. By so setting, the signal C output from the delay circuit 31 rises after the change of the signal A from the low level (VSS) to the high level (VDD) ends, and falls after the change of the signal A from the high level (VDD) to the low level (VSS) ends.

Thus, the signal C rises in the period in which the signal A is at the high level (VDD), and falls in the period in which the signal A is at the low level (VSS). In other words, in the period in which the signal A changes from the low level (VSS) to the high level (VDD), the transistor MP23 is in the ON state to the inverter circuit 21, so that the internal power supply potential VPERI is supplied to the power supply terminal E of the inverter circuit 21. On the other hand, in the period in which the signal A changes from the high level (VDD) to the low level (VSS), the transistor MP24 is in the ON state to the inverter circuit 21, so that the external power supply potential VDD is supplied to the power supply terminal E of the inverter circuit 21.

The signal B output from the inverter circuit 21 is supplied to the inverter circuit 22 arranged in rear of the inverter circuit 21.

The inverter circuit 22 includes a P-channel MOS transistor MP22 and an N-channel MOS transistor MN22 connected in series between the internal power supply potential VPERI and the ground potential VSS. The signal B output from the inverter circuit 21 is supplied in common to gate electrodes of the transistors MP22 and MN22. An output of the inverter circuit 22 is a level-converted output signal OUT.

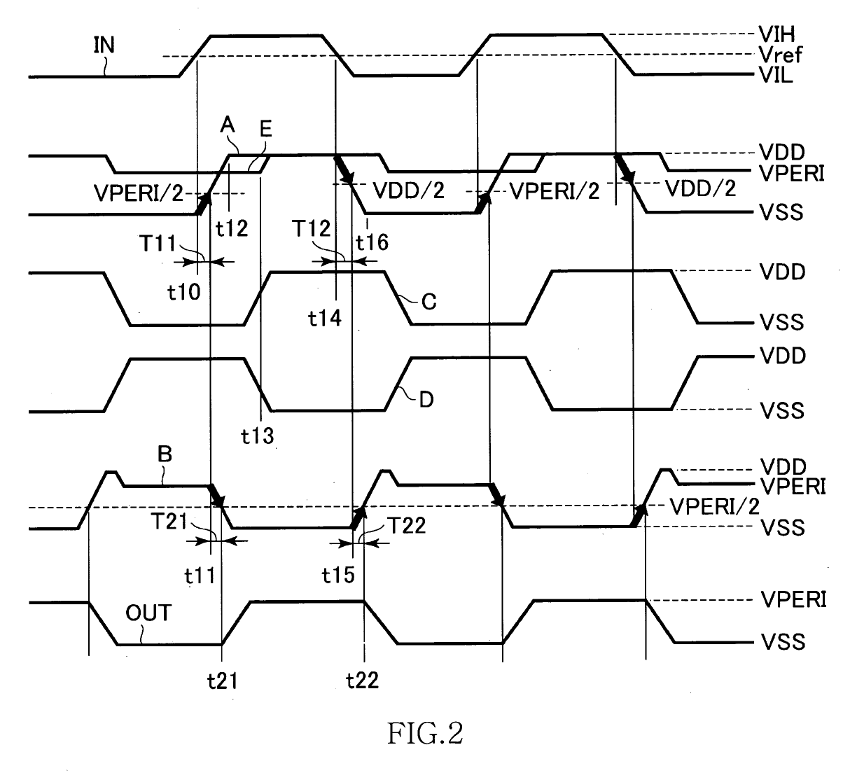

FIG. 2 is a timing chart showing operations performed by the level conversion circuit according to the present embodiment.

First, attention is paid to a period in which the signal A rises from time t10 to time t12. In this period, because the signal C output from the delay circuit 31 is at the low level, the internal power supply potential VPERI is supplied to the power supply terminal E of the inverter circuit 21. Accordingly, in this period, a threshold of the inverter circuit 21 is half the internal power supply potential VPERI, i.e., VPERI/2.

Due to this, it is necessary to take a period T11 in which the signal A rises from VSS to VPERI/2 in order for the signal A to exceed the threshold of the inverter circuit 21. The period T11 corresponds to a delay time produced when the inverter circuit 21 falls. The period T11 is defined as a period necessary for the signal A to change by VPERI/2.

While the inverter circuit 22 receiving the signal B outputs the signal OUT by inverting the signal, as explained above, since the internal power supply potential VPERI is supplied to the power supply terminal of the inverter circuit 22, the threshold of the inverter circuit 22 is VPERI/2. Therefore, it is necessary to take a period T21 in order for the signal B to exceed the threshold of the inverter circuit 22 in which the signal B falls from VPERI to VPERI/2 at time t21. The period T21 corresponds to a delay time produced when the inverter circuit 22 rises. The period T21 is defined as a period necessary for the signal B to change by VPERI/2.

Thereafter, when the signal C output from the delay circuit 31 changes to the high level at time t13, the transistor MP24 turns ON. Therefore, the external power supply potential VDD is supplied to the power supply terminal E of the inverter circuit 21. As a result, the threshold of the inverter circuit 21 changes to half the external power supply potential VDD, i.e., VDD/2.

The signal A rises from time t14 to time t16. In the period from the time t14 to the time t16, the threshold of the inverter circuit 21 is VDD/2 as stated above. Due to this, it is necessary to take a period T12 in which the signal A falls from VDD to VDD/2 in order for the signal A to exceed the threshold of the inverter circuit 21 at time t15. The period T12 corresponds to a delay time produced when the inverter circuit 21 rises. The period T12 is defined as a period necessary for the signal A to change by VDD/2.

Because of VDD>VPERI, the relationship between the delay time T11 at the rising of the inverter 21 and the delay time T12 at the falling of the inverter 21 is represented by T11<T12. That is, a time period corresponding to (T12−T11) is an imbalance produced by level conversion made by the inverter circuit 21, and corresponds to a time necessary for the signal A to change by (VDD-VPER)/2.

It is assumed that VDD is 2.5 V and VPER is 1.8 V. On this assumption, the period T11 corresponds to a change of 0.9 V whereas the period T12 corresponds to a change of 1.25 V. The difference between the changes is as small as a time corresponding to a change of 0.35 V. In the conventional level conversion circuit, the imbalance corresponding to the change of 0.7 V occurs. Therefore, an imbalance amount is reduced to half the imbalance amount produced in a conventional level conversion circuit.

Moreover, a threshold of the inverter circuit 22 receiving the signal B is VPERI/2. Therefore, it is necessary to take a period T22 in which the signal B rises from VSS to VPERI/2 in order for the signal B to exceed the threshold of the inverter circuit 22 at time t22. The period T22 corresponds to a delay time produced when the inverter circuit 22 falls, and is defined as a period necessary for the signal B to change by VPERI/2. The period T22 is substantially identical to the period T21. That is, the difference between the rising edge delay and the falling edge delay is substantially zero in the inverter circuit 22, so that no imbalance occurs.

As explained above, according to the present embodiment, the external power supply potential VDD is supplied as the power supply voltage of the inverter circuit 21 in the period in which the signal A changes from the low level to the high level. Further, the internal power supply potential VPERI is supplied as the power supply voltage of the inverter circuit 21 in the period in which the signal A changes from the high level to the low level. Accordingly, the threshold of the inverter circuit 21 during rising changes from that during falling. As a result, the difference between the delay time T11 produced when the inverter circuit 21 falls and the delay time T12 produced when the inverter circuit 21 rises is smaller than that according to the conventional technique. The level conversion circuit can, therefore, perform level conversion with smaller imbalance. It is thereby possible to ensure a sufficient setup time and hold time of, for example, an address signal synchronous with a clock. In addition, it is thereby possible to ensure that a semiconductor device using the level conversion circuit according to the present embodiment operates at high rate.

The present invention is in no way limited to the aforementioned embodiments, but rather various modifications are possible within the scope of the invention as recited in the claims, and naturally these modifications are included within the scope of the invention.

For example, two inverter circuits are employed as gate circuits for level conversion in the level conversion circuit according to the embodiment. However, the present invention is not limited thereto. Other gate circuits such as NAND circuits can be employed in place of the inverter circuits in the level conversion circuit.

What is claimed is:

1. A level conversion circuit comprising:
a first gate circuit receiving an input signal; and
a switching circuit supplying a first power supply voltage to the first gate circuit in a period in which the input signal changes from a first logic level to a second logic level, and supplying a second power supply voltage different from the first power supply voltage to the first gate circuit in a period in which the input signal changes from the second logic level to the first logic level.

2. The level conversion circuit as claimed in claim 1, wherein the first power supply voltage is lower than an amplitude of the input signal and the second power supply voltage.

3. The level conversion circuit as claimed in claim 2, wherein the second power supply voltage is substantially equal to the amplitude of the input signal.

4. The level conversion circuit as claimed in claim 2, further comprising a second gate circuit receiving an output of the first gate circuit, wherein the first power supply voltage is supplied to the second gate circuit.

5. The level conversion circuit as claimed in claim 4, wherein each of the first gate circuit and the second gate circuit is an inverter circuit.

6. The level conversion circuit as claimed in claim 1, wherein the switching circuit includes
a delay circuit receiving the input signal; and
a power supply circuit supplying one of the first power supply voltage and the second power supply voltage to the first gate circuit based on an output of the delay circuit, wherein
a delay produced by the delay circuit is smaller than a signal width of the input signal.

7. The level conversion circuit as claimed in claim 6, wherein the delay produced by the delay circuit is longer than a rising time of the input signal and a falling time of the input signal.

8. The level conversion circuit as claimed in claim 6, wherein the power supply circuit includes a first transistor and a second transistor that exclusively turn ON based on the output of the delay circuit.

9. A level conversion circuit comprising a first inverter circuit and a second inverter circuit cascade-connected in this order, wherein the first inverter circuit inverts its output signal at a first threshold when its input signal changes from a first logic level to a second logic level, and inverts the output signal at a second threshold different from the first threshold when the input signal changes from the second logic level to the first logic level, and
a threshold of the second inverter circuit is substantially equal to the first threshold.

10. The level conversion circuit as claimed in claim 9, further comprising a switching circuit changing a power supply voltage of the first inverter circuit based on the input signal.

11. A level conversion circuit comprising:
a first inverter circuit;
a first transistor connected between a first power supply potential and a power supply terminal of the first inverter circuit;
a second transistor connected between a second power supply potential and the power supply terminal of the first inverter circuit;
a unit exclusively turning the first transistor and the second transistor ON based on an input signal input to the first inverter circuit; and
a second inverter circuit cascade-connected to the first inverter circuit and having a power supply terminal connected to the first power supply potential.

12. The level conversion circuit as claimed in claim 11, wherein the unit includes a delay circuit producing a delay smaller than a signal width of the input signal and longer than a rising time and a falling time of the input signal.
